(19) United States
(12) Patent Application Publication
(10) Pub. No.: US 2007/0228578 A1
(43) Pub. Date: Oct. 4, 2007

(54) CIRCUIT SUBSTRATE

(75) Inventor: CHIA-HSING CHOU, KAOHSIUNG CITY (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., KAOHSIUNG (TW)

(21) Appl. No.: 11/562,240

(22) Filed: Nov. 21, 2006

(30) Foreign Application Priority Data
Apr. 4, 2006 (TW) 95111890

(51) Int. Cl. H01L 23/48

(52) U.S. Cl. 257/774

(57) ABSTRACT

A circuit substrate including a first wiring layer, a second wiring layer, a first reference plane, a second reference plane, a first conductive via, and a plurality of second conductive vias is provided. The first wiring layer and the second wiring layer have a first signal trace and a second signal trace respectively. The first conductive via is disposed between the first wiring layer and the second wiring layer for connecting the first signal trace with the second signal trace. The second conductive vias are disposed between the first reference plane and the second reference plane for connecting the first reference plane with the second reference plane, wherein the first conductive via is surrounded by the second conductive vias.

### CROSS-REFERENCE TO RELATED APPLICATION

This application claims the priority benefit of Taiwan application serial no. 95111890, filed Apr. 4, 2006. All disclosure of the Taiwan application is incorporated herein by reference.

### BACKGROUND OF THE INVENTION

1. Field of Invention

The present invention relates to a circuit substrate. More particularly, the present invention relates to a circuit substrate with a circuit design capable of preventing internal circuits from being affected by electromagnetic interference.

2. Description of Related Art

Along with the continuous progress of semi-conductor technology, integrated circuit (IC) manufacturers usually fabricate high integration, multifunction, and high speed chips by means of increasing clock frequency, circuit density, and the number of input/output (I/O) terminals etc. of the chips. In general, such a chip is electrically connected to a main board via a chip carrier, such that an electronic signal can be transmitted between the chip and the main board. However, under the circuit design of a conventional chip carrier, the higher the clock frequency of the chip is, the easier the electronic signal is affected by electromagnetic interference.

Generally speaking, a chip carrier is formed by stacking a plurality of conductive layers and a plurality of dielectric layers, wherein the conductive layers include wiring layers, ground planes, and power planes, and one wiring layer is electrically connected to another wiring layer through a plating via.

It should be noted that when two ground planes or two power planes are disposed between two neighboring wiring layers, and when the plating via penetrates through the two ground or power planes to electrically connect one wiring layer to another wiring layer, as a resonant cavity may be formed in the interval between two neighboring ground planes or between two neighboring power planes, if the clock frequency of the electronic signal transmitted between the wiring layers happens to be the resonant frequency of the resonant cavity, a part of energy of the electronic signal is transmitted to the resonant cavity. In other words, when the electronic signal is transmitted from one wiring layer to another wiring layer through a plating via, the signal intensity of the electronic signal may be greatly attenuated, and thus the signal transmission quality between wiring layers is poor.

### SUMMARY OF THE INVENTION

The present invention is directed to a circuit substrate, such that the electronic signal when being transmitted inside the circuit substrate may not be easily interfered by electromagnetic induction.

As embodied and broadly described herein, the present invention provides a circuit substrate, which comprises a first wiring layer, a second wiring layer, a first reference plane, a second reference plane, a first conductive via, and a plurality of second conductive vias. The first wiring layer and the second wiring layer have a first signal trace and a second signal trace respectively. The first conductive via is disposed between the first wiring layer and the second wiring layer for connecting the first signal trace with the second signal trace. The second conductive vias are disposed between the first reference plane and the second reference plane for connecting the first reference plane with the second reference plane, wherein the first conductive via is surrounded by the second conductive vias.

According to an embodiment of the present invention, the second conductive vias are disposed in a circular trace around the first conductive via.

According to an embodiment of the present invention, the first and second reference planes are a ground plane respectively.

According to an embodiment of the present invention, the first and second reference planes are a power plane respectively.

According to an embodiment of the present invention, the first and second wiring layers are a surface wiring layer respectively.

According to an embodiment of the present invention, the first wiring layer is a surface wiring layer and the second wiring layer is an inner wiring layer.

According to an embodiment of the present invention, the first and second reference planes are disposed between the first wiring layer and the second wiring layer.

In view of the above, the current passing through the second conductive vias may form an electric wall which may alleviate the electromagnetic interference to the current in the first conductive via caused by the noises of the first and second reference planes. Therefore, the current passing through the first conductive via can achieve a better signal transmission quality.

In order to make the aforementioned and other objectives, features and advantages of the present invention comprehensible, embodiments accompanied with figures are described in detail below.

### BRIEF DESCRIPTION OF THE DRAWINGS

FIG. 1 is a schematic sectional view of a circuit substrate according to an embodiment of the present invention.

FIG. 2 is a schematic top view of a part of area adjacent to the first conductive via on the circuit substrate in FIG. 1.

FIG. 3 is a schematic sectional view of a circuit substrate according to another embodiment of the present invention.

### DESCRIPTION OF EMBODIMENTS

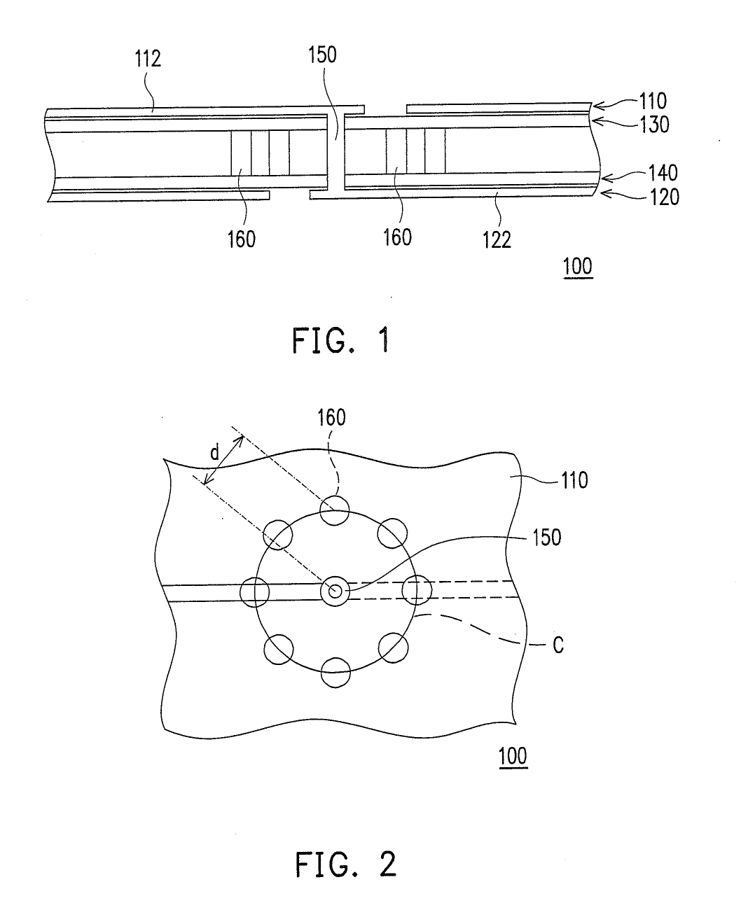

FIG. 1 is a schematic sectional view of a circuit substrate according to an embodiment of the present invention. Referring to FIG. 1, the circuit substrate 100 mainly includes a first wiring layer 110, a second wiring layer 120, a first reference plane 130, a second reference plane 140, a first conductive via 150, and a plurality of second conductive vias 160. As this embodiment mainly describes the relative positions of the first wiring layer 110, second wiring layer 120, first reference plane 130, second reference plane 140, the first conductive via 150, and the plurality of second conductive vias 160, for the convenience of illustration, other wiring layers or reference planes are not shown in FIG. 1.

The first wiring layer 110 has a first signal trace 112. The second wiring layer 120 has a second signal trace 122. The first reference plane 130 and the second reference plane 140 are both ground planes or power planes, and are disposed between the first wiring layer 110 and the second wiring layer 120.

In this embodiment, a dielectric material is disposed between the first wiring layer 110 and the first reference plane 130, the first reference plane 130 and the second reference plane 140, the second reference plane 140 and the second wiring layer 120 respectively, so as to respectively insulate the neighboring first wiring layer 110 and first reference plane 130, first reference plane 130 and second reference plane 140, second reference plane 140 and second wiring layer 120.

The first conductive via 150 is disposed between the first wiring layer 110 and the second wiring layer 120, and penetrates through the first reference plane 130 and the second reference plane 140, such that the first signal trace 112 is electrically connected with the second signal trace 122 through the first conductive via 150. Each of the second conductive vias 160 is disposed between the first reference plane 130 and the second reference plane 140, such that the first reference plane 130 is electrically connected with the second reference plane 140 through the second conductive vias 160.

The first conductive via 150 is surrounded by the second conductive vias 160, so as to be protected from being affected by electromagnetic interference. The mechanism of using the second conductive vias 160 to prevent the first conductive via 150 from being affected by electromagnetic interference in this embodiment will be illustrated in detail below. To further prevent the first conductive via 150 from being affected by electromagnetic interference, in this embodiment, besides disposing the second conductive vias 160 around the first conductive via 150, the second conductive vias 160 can also be arranged following an appropriate trace. FIG. 2 is a schematic top view of a part of area adjacent to the first conductive via on the circuit substrate. In this embodiment, the second conductive vias 160 are arranged in a circular trace C around the first conductive via 150.

The mechanism of using the second conductive vias 160 to protect the first conductive via 150 from being affected by electromagnetic interference will be illustrated below. Referring to FIGS. 1 and 2, when the direction of the current passing through the first conductive via 150 is opposite to the direction of the current passing through the second conductive vias 160, in this embodiment, the overall inductance value (Lₗₒₒₚ) of the first conductive via 150 and the second conductive vias 160 is equivalent to L₁ₛₜ+L_{2nd}−2Lₘ, wherein L₁ₛₜ is the inductance value of the first conductive via 150, L_{2nd} is the inductance value of the second conductive vias 160, and Lₘ is the mutual inductance value between the first conductive via 150 and the second conductive vias 160.

The shorter the distance d between the second conductive vias 160 and the first conductive via 150 is, the greater the mutual inductance value Lₘ between the first conductive via 150 and the second conductive vias 160 will be. Therefore, this embodiment can obtain a smaller inductance value Lₗₒₒₚ by adjusting the distance d. As such, with the arrangement of the second conductive vias 160, in this embodiment, the current inside the first conductive via 150 will not be easily interfered by electromagnetic induction.

Moreover, for the resonant cavity, as in this embodiment, the second conductive vias 160 are disposed in a circular trace C around the first conductive via 150, the current passing through the second conductive vias 160 may form an electric wall surrounding the first conductive via. As such, when a noise exists between the first reference plane 130 and the second reference plane 140, and the frequency of the noise is equal to the resonant frequency of the resonant cavity formed by the first reference plane 130 and the second reference plane 140, the electric wall can prevent the current in the first conductive via 150 from being interfered by the noise. That is, when the current passing through the first conductive via 150 is an electronic signal, with the design of the second conductive vias 160, the electronic signal can be transmitted in the circuit substrate 100 with a better signal transmission quality.

Furthermore, due to the protection of the electric wall formed by the current passing through the second conductive vias 160, the energy of the electronic signal passing through the first conductive via 150 cannot be easily transmitted to the resonant cavity formed by the first reference plane 130 and the second reference plane 140. Therefore, with the design of the second conductive vias 160, this embodiment can prevent attenuating the energy of the electronic signal in the first conductive via 150.

The above descriptions are directed to the concept of the present invention. In other embodiments of the present invention, the aforementioned arrangements of the first wiring layer 110, second wiring layer 120, first reference plane 130, second reference plane 140, first conductive via 150, and the plurality of second conductive vias 160 can be applied in various circuit substrates. The circuit substrates are, for example, multi-layer boards. The first wiring layer 110 or the second wiring layer 120 can be inner wiring layers in addition to surface wiring layers.

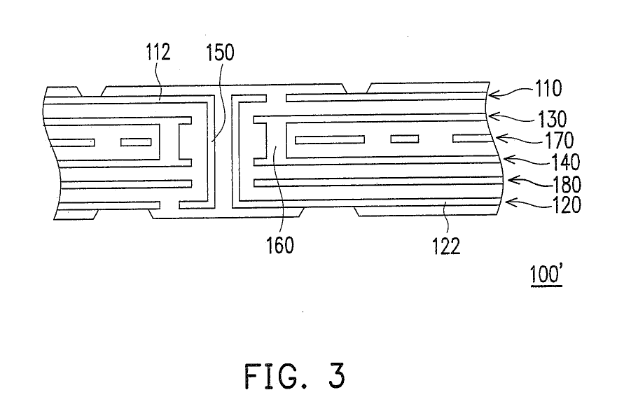

FIG. 3 is a schematic sectional view of a circuit substrate according to another embodiment of the present invention. The circuit substrate 100′ is of a six-layer structure, which also employs the arrangements of the first wiring layer 110, second wiring layer 120, first reference plane 130, second reference plane 140, first conductive via 150, and the plurality of second conductive vias 160 in FIG. 2. A third wiring layer 170 is disposed between the first reference plane 130 and the second reference plane 140, and a third reference plane 180 is disposed between the second reference plane 140 and the second wiring layer 120. In this embodiment, the first reference plane 130 and the second reference plane 140 are ground planes, and the third reference plane 180 is a power plane. Similarly, as in this embodiment, the second conductive vias 160 are disposed around the first conductive via 150, the current of the circuit substrate 100′ flowing inside the first conductive via 150 is not easily interfered by electromagnetic induction. Definitely, to further protect the current in the first conductive via 150 from being interfered by electromagnetic induction, in this embodiment, the second conductive vias 160 can be arranged in a circular trace around the first conductive via 150.

It should be noted that the concept of the present invention mainly involves disposing the second conductive vias around the first conductive via. The first conductive via is disposed between two conductive layers and electrically connects the two layers. The second conductive vias are disposed between two reference planes and electrically connect the two reference planes. Accordingly, based on this concept, the present invention can adopts more than two wiring layers, a plurality of ground planes, and a plurality of power planes as required.

In view of the above, when the current flowing from other parts of the circuit substrate into the first reference plane and the second reference plane or flowing from the first reference plane and the second reference plane into other parts of the circuit substrate passes through the second conductive vias, as the second conductive vias are disposed around the first conductive via, the current flowing in or out can be used to reduce the overall inductance value (Lₗₒₒₚ) of the first conductive via and the second conductive vias. Furthermore, when a noise exists between the first reference plane and the second reference plane, as the current passing through the second conductive vias may form an electric wall, the current in the first conductive via is not easily interfered by the noise. As the overall inductance value (Lₗₒₒₚ) of the first conductive via and the second conductive vias is low, when transmitting signals, the circuit substrate provided by the present invention has a lower synchronous switching noise (SSN). As the current passing through the second conductive vias may form an electric wall, the design of the second conductive vias of the present invention may alleviate the electromagnetic interference to the current in the first conductive via caused by the noises of the first and second reference planes. Therefore, the electronic signal can be transmitted in the first conductive via with a better signal transmission quality.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A circuit substrate, comprising:
a first wiring layer having a first signal trace;
a second wiring layer having a second signal trace;
a first reference plane;
a second reference plane;
a first conductive via disposed between the first wiring layer and the second wiring layer for connecting the first signal trace with the second signal trace; and
a plurality of second conductive vias disposed between the first reference plane and the second reference plane for connecting the first reference plane with the second reference plane, wherein the first conductive via is surrounded by the second conductive vias.

2. The circuit substrate as claimed in claim 1, wherein the second conductive vias are disposed in a circular trace around the first conductive via.

3. The circuit substrate as claimed in claim 1, wherein the first reference plane and the second reference plane are a ground plane respectively.

4. The circuit substrate as claimed in claim 1, wherein the first reference plane and the second reference plane are a power plane respectively.

5. The circuit substrate as claimed in claim 1, wherein the first wiring layer and the second wiring layer are a surface wiring layer respectively.

6. The circuit substrate as claimed in claim 1, wherein the first wiring layer is a surface wiring layer and the second wiring layer is an inner wiring layer.

7. The circuit substrate as claimed in claim 1, wherein the first reference plane and the second reference plane are disposed between the first wiring layer and the second wiring layer.
